(19) United States
(12) Patent Application Publication
(10) Pub. No.: US 2014/0154874 A1
(43) Pub. Date: Jun. 5, 2014

(54) METHOD OF MAKING SEMICONDUCTOR MATERIALS AND DEVICES ON SILICON SUBSTRATE

(71) Applicant: THE BOARD OF REGENTS OF THE UNIVERSITY OF OKLAHOMA, Norman, OK (US)

(72) Inventor: Zhisheng Shi, Norman, OK (US)

(73) Assignee: THE BOARD OF REGENTS OF THE UNIVERSITY OF OKLAHOMA, Norman, OK (US)

(21) Appl. No.: 14/174,618

(22) Filed: Feb. 6, 2014

Related U.S. Application Data
(63) Continuation of application No. 13/168,290, filed on Jun. 24, 2011, now abandoned.

(51) Int. Cl. H01L 21/02

(52) U.S. Cl. CPC H01L 21/02639
USPC 438/478

(57) ABSTRACT

A crystalline structure comprising a substrate, which has a surface. The surface has one or more wells formed therein defining one or more growing area and at least one layer of dissimilar crystalline material epitaxially grown on the growing area. A method of making a crystalline structure having a low threading dislocation density comprising the steps of (a) patterning a surface of a substrate material such that one or more wells defining a growing area is formed therein; and (b) epitaxially growing at least one strained layer of dissimilar crystalline material on the growing area of the surface of the substrate material, such that the threading dislocation density of the at least one strained layer is reduced by the one or more wells.

### INCORPORATION BY REFERENCE

The entirety of the following patents and patent application are hereby expressly incorporated herein by reference: U.S. Application Ser. No. 13/168,290.

### STATEMENT REGARDING FEDERALLY SPONSORED RESEARCH OR DEVELOPMENT

This invention was made with government support under Grant Number W911NF-07-1-0587 awarded by the Army Research Office (ARO). The government has certain rights in this invention.

### BACKGROUND

A semiconductor is a solid whose electrical conductivity can be controlled. Semiconductor devices are electronic components made of semiconductor materials. To manufacture semiconductors, a method called epitaxial growth is typically used. An epitaxy is the interface between a thin film or layer of material and a substrate.

Crystalline materials are made up of atoms arranged in a lattice characterized by a certain distance between the atoms (i.e. the lattice constant of the particular crystalline material). The ordinary epitaxial growth method is limited because generally the materials used must have the same lattice constant. If a material used has a lattice constant different than the substrate, the difference between the two constants is called a lattice mismatch or heteroepitaxy. The lattice mismatch creates a strain on the atom bonds. If the dissimilar material is grown to a thickness below a parameter known in the art as a “critical thickness,” the lattice mismatch is compensated by the strain. If, however, the dissimilar material is grown beyond the critical thickness, a dislocation (defect) in the crystal can form, hindering the mobility of the electrons and thus decreasing the conductivity. The critical thickness varies inversely with the lattice mismatch (e.g. the larger the mismatch, the smaller the critical thickness and vice versa).

Crystalline defects, including dislocations, can limit the performance of low-defect-density crystalline structures whose functions are usually derived from a particular combination of layered materials with different electronic, magnetic, opto-electronic properties, and the like. In most cases, the lattice constant of the materials of the constituent layers also differ. It is well known that dislocations can be created, or elongated, at epitaxial interfaces when a material, whose lattice constant is different from that of the substrate, is grown beyond the critical thickness.

Heteroepitaxy of lead salt films and/or layers like PbSe and Pb₁₋ₓSnₓSe has widespread applications in solid state devices such as mid-infrared (IR) light-emitting and laser diodes (Ref. 1-2), mid-IR sensors (Ref. 3), thermoelectric coolers, and power generators (Ref. 4), for example. Lead salt film and/or layers growth on silicon substrates (hereinafter referred to as Si substrates) have attracted great interest due to the availability and scalability of Si substrate, and the integration with Silicon-based integrated circuits (IC). Because of the primary {100}<110> silicon dislocation glide system, epitaxial growth on Si(111) has been proven to produce the best material quality (Ref. 5).

However, high threading dislocation densities of the as-grown lead salt epitaxial layer via molecular beam epitaxy (MBE) in the range of 3×10⁷˜1”10⁸ cm⁻² still limit device performance. By ex-situ temperature cycling, the dislocation density can be reduced by over an order of magnitude (Ref. 6), but the process may contaminate the epitaxial layer.

Heteroepitaxy of semiconductor films on Si substrates has attracted great interest due to the availability and scalability of Si substrate, the integration with Silicon-based integrated circuits (IC) and the good mechanical and thermal properties of Si substrate. Many semiconductor devices have been fabricated on Si substrate, such as MCT detectors on Si, for example. However, due to the differences in lattice constant and thermal expansion coefficients semiconductor films grown on a dissimilar Si substrate have high threading dislocation densities and limit the device performance. Therefore, developing a method that could significantly reduce the dislocation density for dissimilar semiconductor materials epitaxially grown on a Si substrate is very desirable.

To that end, a need exists for a growth method, preferably utilizing molecular beam epitaxy, which can reduce threading dislocation densities in an as-grown dissimilar semiconductor material on a dissimilar substrate such as Si substrate. It is to such a method, and semiconductor devices produced by such method, that the instant inventive concept is directed.

### SUMMARY

In one aspect, the inventive concept disclosed herein is directed to a crystalline structure, comprising a substrate comprising a surface having one or more wells formed therein defining one or more growing area, and at least one layer of dissimilar crystalline material epitaxially grown on the growing area.

In another aspect, the inventive concept disclosed herein is directed to a crystalline structure, comprising a substrate comprising a surface having a first well, a second well and a third well spaced apart to define a growing area therebetween. The substrate has a first lattice constant, at least one layer of a crystalline material epitaxially grown on the growing area of the substrate, the crystalline material having a second lattice constant that is different from the first lattice constant.

In another aspect, the inventive concept disclosed herein is directed to a method of making a crystalline structure having a low threading dislocation density comprising the steps of (a) patterning a surface of a substrate material such that one or more wells defining a growing area is formed therein; and (b) epitaxially growing at least one strained layer of dissimilar crystalline material on the growing area of the surface of the substrate material, such that the threading dislocation density of the at least one strained layer is reduced by the one or more wells.

In yet another aspect, the inventive concept disclosed herein is directed to a semiconductor device comprising a crystalline structure comprising a substrate comprising a surface having one or more wells defining a growing area formed therein, and at least one strained layer epitaxially grown on the growing area of the surface of the substrate.

### BRIEF DESCRIPTION OF THE SEVERAL VIEWS OF THE DRAWINGS

So that the above recited features and advantages of the present inventive concept can be understood in detail, a more particular description of the inventive concept, briefly summarized above, may be had by reference to the embodiments thereof that are illustrated in the appended drawings. It is to be noted, however, that the appended drawings illustrate only typical embodiments of the inventive concept and are therefore not to be considered limiting of its scope, for the invention may admit to other equally effective embodiments. The appended drawings are not necessarily to scale, and certain features and views of the drawings may be shown exaggerated in scale or in schematic, in the interest of clarity and conciseness.

FIG. 1 is a diagram of a patterned substrate according to the instant disclosure.

FIG. 2 is a top view scanning electron microscope image of a patterned Si substrate having a buffer layer and a layer of semiconductor material epitaxially grown on the Si substrate according to the instant disclosure.

FIG. 3A is a scanning electron microscope image of an area 1 of FIG. 1.

FIG. 3B is a scanning electron microscope image of an area 2 of FIG. 1.

FIG. 4 is a cross-sectional diagram of a patterned Si substrate having a buffer layer and the layer of semiconductor material, such as lead salt deposited thereon.

FIG. 5 is a block diagram showing steps comprising a method of making a semiconductor structure according to the instant disclosure.

### DETAILED DESCRIPTION

Before explaining at least one embodiment of the inventive concept disclosed herein in detail, it is to be understood that the inventive concept is not limited in its application to the details of construction and the arrangement of the components or steps or methodologies set forth in the following description or illustrated in the drawings. The inventive concept disclosed herein is capable of other embodiments or of being practiced or carried out in various ways. Also, it is to be understood that the phraseology and terminology employed herein is for the purpose of description and should not be regarded as limiting in any way.

In the following detailed description of embodiments of the disclosure, numerous specific details are set forth in order to provide a more thorough understanding of the inventive concept. However, it will be apparent to one of ordinary skill in the art that the inventive concept within the disclosure may be practiced without these specific details. In other instances, well-known features have not been described in detail to avoid unnecessarily complicating the instant disclosure.

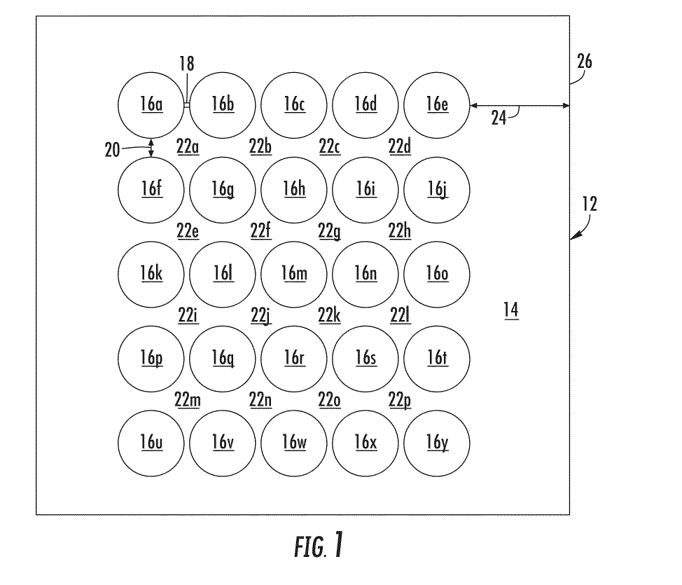

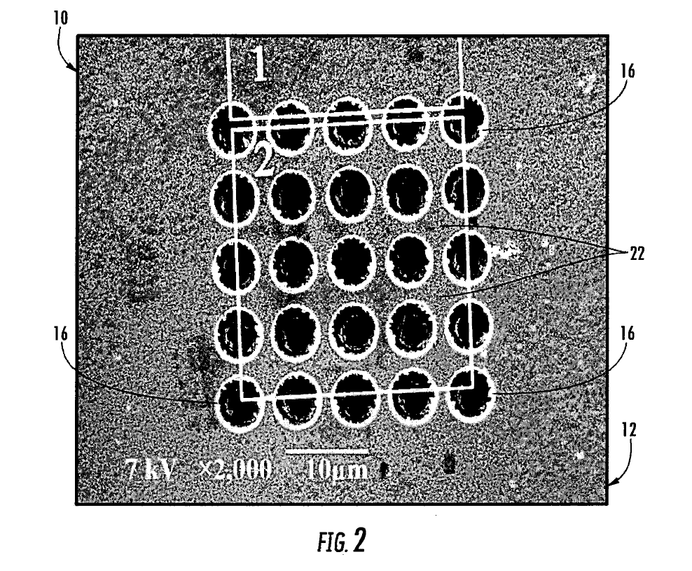

The inventive concept disclosed herein is generally related to a crystalline structure 10 (shown in FIG. 2). The crystalline structure 10 is provided with a substrate 12, which is shown by way of example in FIG. 1. The substrate 12 is also referred to herein as a “patterned substrate.” The substrate 12 is constructed of a crystalline material that has properties desirable for constructing semiconductor-based devices, such as integrated circuits and/or lasers, for example. For example, the substrate 12 can be a wafer, such as a silicon crystal, used in the fabrication of integrated circuits and/or other micro devices. Alternative materials, such as compound III-V or II-VI semiconductor materials can also be employed. For example, gallium arsenide (GaAs), a III-V semiconductor produced by a Czochralski process can also be employed.

The substrate 12 is provided with a surface 14 which is patterned with one or more wells 16a-y. The surface 14 is aligned in one of several relative directions known as crystal orientations. Orientation can be defined with what is known as the Miller index with [100] or [111] orientations being the most common for silicon. The substrate 12 can be provided with an initial doping concentration as known in the art to assist in the fabrication of certain types of semiconductor devices.

The wells 16a-y are spaced a distance apart from each other as shown in FIG. 1, but are sufficiently close together to achieve the reduction in threading dislocation density of material epitaxially grown on the surface 14 as will be discussed in more detail below. For example, the well 16a is spaced a first distance 18 from the well 16b, and a second distance 20 from the well 16f. The first distance 18 can be the same as or different than the second distance 20. In one version, the first distance 18 is the same as the second distance 20 and about 1.5 micrometer. However, it should be understood that the first distance 18 and the second distance 20 can vary. Further, the well 16e is spaced at a distance 24 from an edge 26 of the substrate 12. The distance 24 may be, for example 5 mm, or any other desired distance, as will be understood by persons of ordinary skill in the art. The wells 16a-y cooperate to define and/or substantially surround a plurality of distinct growing areas 22a-p of the surface 14 for fabricating one or more semiconductor device in each of the growing areas 22a-p.

The sizes of the wells 16a-y can vary, but in general, the wells 16a-y are provided with a depth that prevents epitaxial growth of crystalline material on top of the wells 16a-y. It has been found that a suitable depth for the wells 16a-y is about 3 microns, although greater or lesser depths may be employed. The wells 16a-y can be formed into the surface 14 of the substrate 12 using any suitable technique, such as cutting and/or a process of photolithography followed by an etching process. The etching process used to form the wells 16a-y may be a dry etching process, such as plasma etching, or may be a wet etching process, for example. It has been found that at least one layer of dissimilar crystalline material can be epitaxially grown on the growing areas 22a-p, and that such dissimilar crystalline material will have a significant reduction of dislocations as compared to the dissimilar crystalline material being epitaxially grown on the substrate 12 without the presence of the wells 16a-y.

The term “dissimilar crystalline material” as used herein refers to the crystalline material being different in lattice constant from the lattice constant of the substrate 12. An example of a dissimilar crystalline material described herein is a lead salt material, such as lead selenium, when the substrate 12 is a Si substrate.

### EXAMPLES

Examples of implementations of the inventive concept disclosed herein will be set forth. However, it should be understood that the claimed subject matter is not limited to these examples.

More particularly, but not by way of limitation, the inventive concept disclosed herein is directed to a method of growing one or more semiconductor materials via MBE, for example, that can reduce threading dislocation densities in as-grown dissimilar lead salt epitaxial layers onto one or more substrates and to devices manufactured from the semiconductor materials produced therewith.

In one exemplary embodiment, the substrate 12 can be 1 cm×1 cm silicon wafer having a (111) orientation. It is to be understood, however, that in a commercial embodiment the substrate 12 may comprises a larger wafer, such as a 20 cm×20 cm wafer, for example. The surface 14 may be patterned before growth to produce a matrix of 5×5 wells 16 as shown in FIG. 2. It is to be understood that the number of wells 16 used, the orientation of the wells 16 relative to one another, and the shape, size, and depth of the wells 16 can be varied as will be understood by persons of ordinary skill in the art presented with the instant disclosure. For example, a triangular, rectangular, elliptical, or circular group of wells 16 may be used instead of a square matrix. One or more of the wells 16 preferably cooperate to define one or more growing areas 22 on the surface 14 of the substrate 12 between the wells 16.

Once the appropriate orientation and number of wells 16 is selected and patterned onto the surface 14 of the Si substrate 12, the Si substrate 12 may be dry etched using, for example, a deep reactive ion etching (RIE) system to produce the pattern with an exemplary etch depth of 3 μm. The surface 14 of the patterned Si substrate 12 and another 1 cm×1 cm un-patterned Si substrate can be cleaned for epitaxial growth.

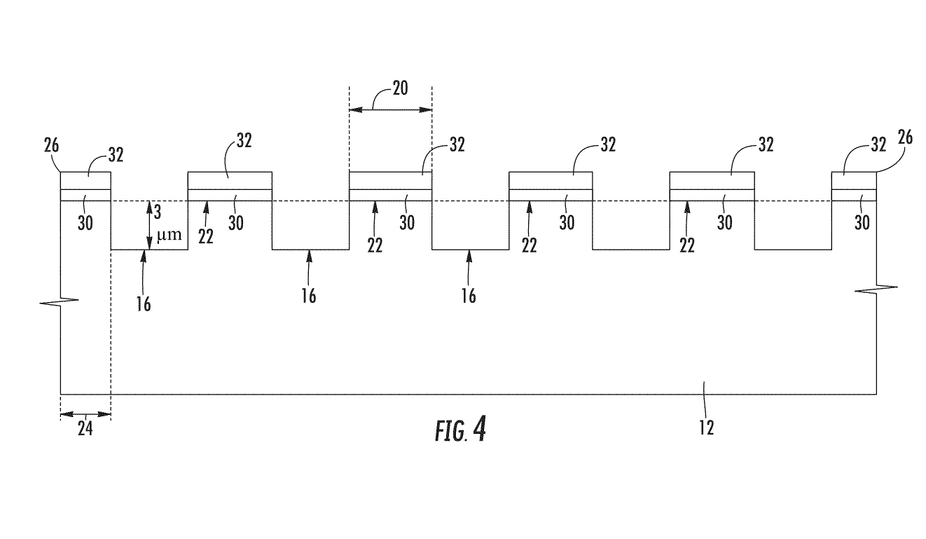

In one embodiment, a two-chamber MBE system may be used for the growth. A layer 30 (shown in FIG. 4) comprising CaF2 and having a thickness of approximately 2 nm (or of any other thickness which is within the critical thickness) can be grown onto the surface 14 as a buffer layer in one chamber under vacuum. However, other buffer layers 30 comprising other materials and/or having varying thickness, such as BaF₂, for example, may also be used with the instant inventive concept, as will be understood by persons of ordinary skill in the art presented with the instant disclosure.

At least one, and preferably one or more, epitaxial layer 32 of dissimilar PbSe crystalline material can then be epitaxially grown over the growing areas 22 defined by the one or more wells 16 on the layer 30 and the surface 14 of the CaF₂/Si substrate 12 in another chamber, without breaking the vacuum, for example. The temperature of the Si substrate 12 preferably remains at 420° C. during the growth. The thickness of the PbSe epitaxial layer 32 can be, for example 1.8 μm as measured by scanning electron microscopy (SEM) or any other desired thickness It is to be understood that the at least one layer 32 may comprise other lead salts such as Pb₁₋ₓSnₓSe, and combinations of two or more lead salts, or other suitable semiconductor materials, for example.

A wet chemical etching process as described in Ref. 7 may then be undertaken to reveal threading dislocations of the PbSe film as etch pits on both patterned and un-patterned substrates. FIG. 2 shows a top view scanning electron microscope image of a PbSe film grown on a patterned Si(111) substrate after a wet chemical etching process. The minimum edge-to-edge spacing between adjacent wells 16 may be 1.5 μm, for example. It is to be understood that the edge-to-edge spacing between adjacent wells 16 may vary.

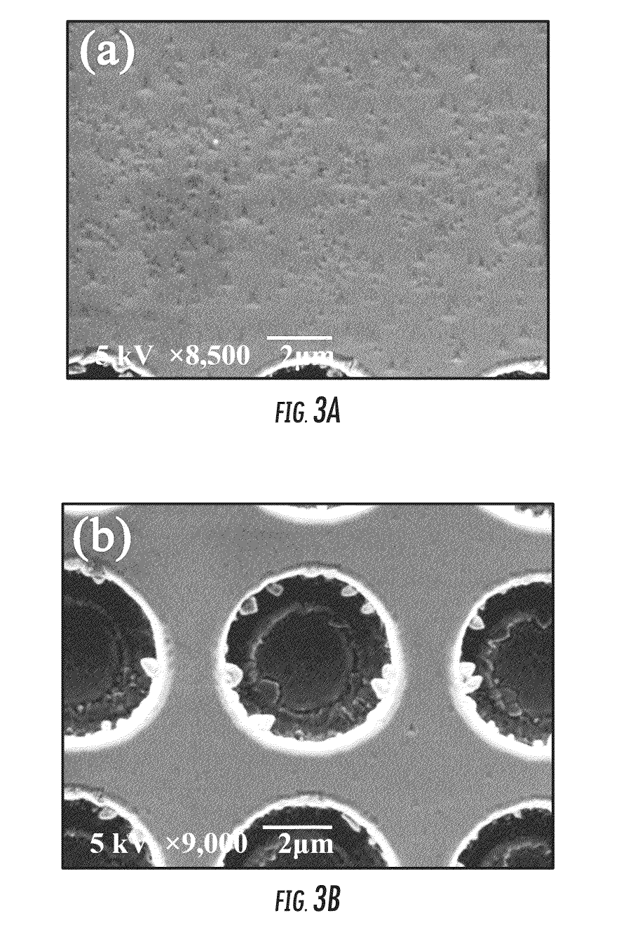

The un-patterned spacing from the edge of the wells 16 to an edge 34 of the substrate 12 can be about 5 mm, which spacing may be intentionally selected to compare with the growth on the un-patterned substrate. This spacing area is marked as area 1. The layer 32 (or film) grown on the patterned structure is marked as area 2. Close-up SEM images shown in FIG. 3A and FIG. 3B were taken in both areas.

FIG. 3A is the SEM image inside the area 1 that shows etch pits of triangle shape for the PbSe film grown on Si(111) substrate 12. The etch pit density (EPD) in area 1 is counted to be around 1×10⁸ cm⁻², which is consistent with the result obtained from the PbSe layer grown on un-patterned substrate in the same MBE run. However, the EPD in area 2 is significantly lower than that in area 1. Many of the periodic elements in area 2 are free of etch pits. FIG. 3B shows the SEM image from the center of area 2. There is only one etch pit observed, and thus, the EPD is calculated to be 9×10⁵ cm⁻². Possible mechanisms which may be causing this significant dislocation reduction will be discussed below.

It is well known that the strain induced by misfit in IV-VI material on Si(111) substrate is mainly relieved through glide of dislocations in the {100}<110> glide system (Ref. 5). Also, it has been predicted that most threading ends remain extremely mobile and can cross the whole sample with cm size by applying temperature cycles (Ref. 6 and 8). However, the number of threading dislocations that can be removed by glide in IV-VI material has not been analyzed, while a similar issue in III-V material system has already been discussed (Ref. 9).

In IV-VI material system, the average separation of parallel misfit dislocations is inter-correlated with the plastic strain ε and is given by s=3/2·b_{eff}·ε⁻¹, where b_{eff}˜2.5 Å is the projection of the Burgers vector responsible for strain relief (Ref. 8). Here, the side length L of the sample is assumed to be parallel to the glide direction <110>. If all threading dislocations glide to the sample edge, then the average length of misfit dislocation is L/2. If the number of threading dislocations per unit area is ρ, then it follows from geometry for three-fold symmetry s·L·ρ=6 (Ref. 8). Thus, the density of threading dislocations that can be removed by glide is ρ=4·ε/(b_{eff}·L). Therefore, its upper limit is obtained by setting ε equal to the misfit f and expressed as:

$${ρ}_{max} = \frac{4 \cdot f}{{b}_{eff} \cdot L}$$

For the above referenced samples, L is 4.5 μm for PbSe film on patterned Si(111) which is the maximum edge to edge spacing between adjacent wells 16, and 1 cm for PbSe film grown on the un-patterned Si(111). For PbSe grown on Si(111), the induced lattice misfit strain is approximately 12% at growth temperature and thermal mismatch strain created by temperature change from growth temperature to room temperature is approximately 0.87%. The calculated upper limits to the density of threading dislocations that can be removed by glide for the PbSe samples on patterned and un-patterned Si(111) are listed in Table 1. It is to be understood that the term “approximately” as used herein is intended to mean not only the exact number specified, but also variations due to measurement and/or processing errors, as well as errors inherent in the measurement methods and/or equipment used.

TABLE 1
The upper limits of threading dislocation density removed by glide.

| | Upper limits (cm⁻²) due to | | |
|---|---|---|---|
| PbSe films on | lattice misfit | thermal mismatch | Total |
| patterned Si | 4.5 × 10¹⁰ | 2.3 × 10⁹ | 4.73 × 10¹⁰ |
| un-patterned Si | 2.0 × 10⁷ | 1.1 × 10⁶ | 2.31 × 10⁷ |

The limits in Table 1 were calculated by assuming that the PbSe was fully strained. In reality, most of the strain due to lattice mismatch is relaxed for layers thicker than the critical thickness which for PbSe is approximately 2.6 nm. Therefore, the actual limits to the density of threading dislocation that can be removed by glide due to lattice mismatch strain should be less than that listed in Table 1 for both cases. Thus, the thermal mismatch strain could be dominating. Nonetheless, no matter which strain is dominating, it is clearly shown that the upper limit for PbSe on patterned Si (111) is of over three orders of magnitude larger than that for PbSe on the un-patterned Si (111). The EPD of in-situ grown PbSe films on the un-patterned Si(111) is typically in the range of 3×10⁷˜1×10⁸ cm⁻², which is an indication that above mentioned mechanism will not be able to reduce dislocation to below 10⁷ cm⁻². On the contrary, the PbSe film on patterned Si(111) is capable of removing the mobile threading dislocations higher than 10⁹ cm⁻² by glide. This offers an explanation of the low EPD reported in this disclosure.

This result may also be used to explain the reported ex-situ high temperature cycling process to reduce dislocation density for IV-VI films on planar Si(111) (Ref. 6). As additional stresses build up during the temperature cycle, according to the above analysis, the density of threading dislocations that can be removed by glide increases linearly with the strain induced.

However, introducing additional stresses by applying numerous temperature cycles also increases the threading dislocation density ρ in planar epitaxial PbSe on Si(111) (Ref. 5 and 6), which suggests that certain dislocation nucleation sources may be activated. For the growth on patterned substrate 12, it is believed that the lateral dimension related nucleation sources may be partially or completely suppressed. This may be another mechanism for reduction of threading dislocation density. The lateral dimension dependent dislocation nucleation sources may include dislocation multiplication by threading dislocation interaction, and surface dislocation nucleation generated by thermal mismatch strain.

Dislocation multiplication is a dislocation nucleation mechanism that has been researched in detail (Ref. 9-10). J. W. Matthews et al. indicated that the conditions to prevent multiplication are those that avoid interaction of threading dislocations (Ref. 9). If the threading ends of two dislocations moving in different glide planes encounter one another, the geometrical probability for one moving threading dislocation meets another threading dislocation is given by p·1=1/ρ, where I is the mean free path of a threading dislocation, and p=t·sin θ is the width of the glide plane projection with layer thickness t and the angle θ between the (100) glide plane and the normal to the interface plane. The calculated mean free path is 0.375 μm for the PbSe film grown on the substrate 12 when the substrate 12 is Si(111). Assuming one threading dislocation glides through one edge to another, the dislocation interactions will happen twelve times for the sample grown on patterned Si(111). However, for the 1×1 cm² sample grown on un-patterned Si(111), the interaction will be 2.7×10⁴ times, which is three orders of magnitude larger than that on patterned Si(111). It means that the dislocation multiplication would be more rare and dislocation escape would be more common in the film grown on patterned Si(111), in contrast to the film on un-patterned Si(111).

Further, thermal residual stress is another known lateral dimension dependent dislocation nucleation mechanism. It is well known that PbSe material has a larger thermal coefficient than Si; therefore, the thermal mismatch would induce residual stress after growth of PbSe film on Si substrates. As a result, considerable dislocations may form to relieve the stress. Here, a model to explain the effect of edge-to-edge spacing reduction to thermal stress may be applied (Ref. 11), which has been proven to be valid in epitaxial III-V material systems (Ref. 12). Thermal residual stress in the epitaxial film can be expressed as follows:

σ(x)=σ₀·(1−e^{-k·(1/2-x)}),

with

$$\{ \begin{matrix}{σ}_{0} = \frac{Δ α \cdot Δ T}{λ \cdot {t}_{PbSe}} \cdot ( 1 + \frac{3 \cdot ( {t}_{PbSe} + {t}_{Si} ) \cdot {D}_{PbSe}}{( {D}_{PbSe} + {D}_{Si} ) \cdot {t}_{PbSe}} ) \\ λ = \frac{1}{12} ( \frac{{t}_{PbSe}^{2}}{{D}_{PbSe}} + \frac{{t}_{Si}^{2}}{{D}_{Si}} + \frac{3 \cdot {( {t}_{PbSe} + {t}_{Si} )}^{2}}{{D}_{PbSe} + {D}_{Si}} ) \\ k = \sqrt{\frac{2 λ}{3} \cdot ( \frac{1 + {v}_{PbSe}}{l \cdot {E}_{PbSe}} + \frac{1 + {v}_{Si}}{l \cdot {E}_{Si}} )} \\ {D}_{i} = \frac{{E}_{i} \cdot {t}_{i}^{3}}{12 \cdot ( 1 - {v}_{i}^{2} )} ,\end{matrix}$$

where Δα is the difference of thermal expansion coefficient between PbSe and Si, ΔT is the variation between growth and room temperature, E is Young's modulus, t is the thickness, v is Poisson's ratio, I is the lateral edge-to-edge width, and x is the distance from the center of patterned film, respectively. Calculated results show that the average thermal stress for the film grown on un-patterned Si(111) is 4.4×10⁸ Pa, and that for the film on patterned Si(111) is 1.6×10⁸ Pa. All material parameters are taken from Ref. 5, and Young's modulus and Poisson's ratio are calculated by the theory from Ref. 13. It was found that the square-root relationship between film stress and dislocation density in rocksalt structure crystals can be expressed as follows (Ref. 14):

σ=A·\sqrt{N_{d}},

where A is a constant, Nd is measured dislocation density. Since such thermal stress created by patterned structure decreases three times, the dislocation density generated by such thermal residual stress should be almost an order of magnitude lower on patterned substrate 12 than that on un-patterned substrate.

In summary, with the combination of the promoted dislocation glide and reduction of dislocation multiplication, the dislocation density on patterned substrate 12 can be significantly reduced as evidenced by the experimental result of 9×10⁵ cm⁻². Optimization of the pattern parameters could lead to further dislocation reduction. Epitaxial films with such low dislocation density should have significant implications for device fabrication on Si. The growth method could also be applied to other material systems grown on Si and/or other dissimilar substrates.

The instant inventive concept offers a method that will significantly reduce the dislocation density for heteroepitaxial semiconductor films on Si, for example, patterned substrates 12. Therefore it will significantly improve the state-of-the-art of current semiconductor devices on Si and open doors for other advanced semiconductor devices fabricated on Si substrate that have not been tried previously.

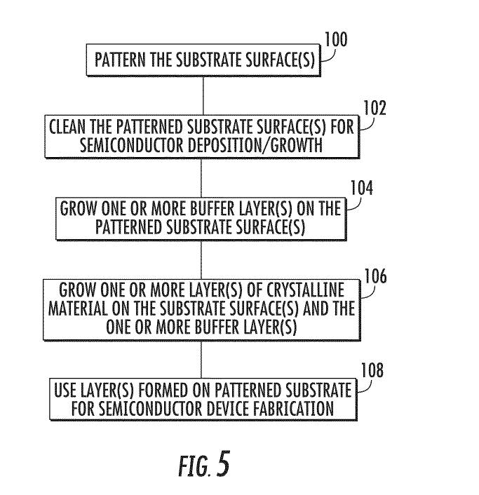

Referring now to FIG. 5, a method according to the instant disclosure comprises the following steps:

In a step 100, one or more surface(s) 14 of the substrate 12 is patterned, for example, by etching. Next, in a step 102, the one or more patterned substrate surface(s) 14 may be cleaned and/or otherwise prepared for semiconductor growth thereon. In a step 104, one or more buffer layers 30 may be grown (for example, by using MBE, MOCVD, etc) on the patterned surface(s) 14 of the substrate 12. Such layers 30 preferably comprise a first buffer layer 30 comprising CaF₂, BaF₂, and combinations thereof. Next, in a step 106, one or more thin semiconductor material layers 32 may be epitaxially grown on the buffer layer 30 grown in step 104. Such layers preferably comprise a layer 32 of PbSe, Pb₁₋ₓSnₓSe, and combinations thereof. Next, in a step 108, the semiconductor layers 32 with low dislocation density formed on patterned substrate 12 may be used for device fabrication as will be understood by a person of ordinary skill in the art. Such use may comprise further modifying the semiconductor material by, for example, doping predetermined parts of the crystalline structure, and/or forming at least one or one or more of a conductive path, an optical waveguide, an electronic, or an optical component, and combinations thereof.

Further, rather than patterning and depositing a layer of semiconductor material 32 on a single surface 14 of the substrate 12, two, three or more surfaces 14 of the Si substrate 12 may be patterned and have one or more buffer layers 30 and/or one or more layers of semiconductor materials 32 grown or deposited thereon as described above. Further, a combination of one or more patterned surface 14 and one or more unpatterned surface may have one or more buffer layers 30 and/or one or more layers of semiconductor materials 32 grown or deposited thereon as described above.

The patterned substrate 12 with reduced lateral dimension of epitaxial layer 32 could increase the upper limit number of the threading dislocations that can be removed by glide, and also decrease the dislocation generation through suppressing lateral dimension dependent nucleation sources. Those sources include dislocation interactions and surface nucleation generated by thermal mismatch strain. Consequently, remarkable threading dislocation reduction could be achieved.

The material used to demonstrate the above method is IV-VI lead salt semiconductors. However, it is to be understood that this method is not limited to IV-VI materials, but may be used with other semiconductor materials.

Further, it is believed that all semiconductor thin-film devices fabricated on Si substrate could benefit from this invention, for example, mid-/long-infrared detector arrays on Si using epitaxial films of MCT and IV-VI lead salt materials on Si, semiconductor lasers on Si such photonic crystal lasers, semiconductor sensors on Si substrate, and semiconductor thermoelectric devices on Si.

### REFERENCES

The below references are incorporated herein in their entirety:

Reference 1—D. L. Partin, IEEE J. Quantum Electron. 24, 1716-1726 (1988).

Reference 2—M. Tacke, Infrared Phys. Technol. 36, 447-463 (1995).

Reference 3—H. Zogg, Proc. SPIE 3890, 22-26 (1999).

Reference 4—T. C. Harman, P. J. Taylor, M. P. Walsh, and B. E. LaForge, Science 297, 2229-2232 (2002).

Reference 5—H. Zogg, S. Blunier, A. Fach, C. Maissen, P. Müller, S. Teodoropol, V. Meyer, G. Kostorz, A. Dommann and T. Richmond, Phys. Rev. B 50 (15), 10801-10810 (1994).

Reference 6—P. Müller, H. Zogg, A. Fach, J. John, C. Paglino, A. N. Tiwari, M. Krejci, and G. Kostorz, Phys. Rev. Lett. 78 (15), 3007-3010 (1997).

Reference 7—A. Fach, J. John, P. Müller, C. Paglino, and H. Zogg, J. Electron. Mater. 26 (7), 873-877 (1997).

Reference 8—H. Zogg, P. Müller, A. Fach, J. John, C. Paglino, S. Teodoropol, Mat. Res. Soc. Symp. Proc. 379, 27-32 (1995).

Reference 9—J. W. Matthews, A. E. Blakeslee and S. Mader, Thin Solid Films 33 (2), 253-266 (1976).

Reference 10—E. Suhir, J. Appl. Mech-T Asme. 53 (3), 657-660 (1986).

Reference 11—M. Yamaguchi, M. Tachikawa, M. Sugo, S. Kondo and Y. Itoh, Appl. Phys. Lett. 56 (1), 27-29 (1990).

Reference 12—R. Hill, P. Phys. Soc. Lond. A 65 (389), 349-355 (1952).

Reference 13—W. Hagen and H. Strunk, Appl. Phys. 17, 85-87 (1978).

Reference 14—M. T. Sprackling, The plastic deformation of simple ionic crystals. (Academic Press, London; N.Y., 1976).

What is claimed is:

1. A method of making a IV-VI crystalline structure, comprising:
patterning a surface of a substrate material with a plurality of wells thereby defining a growing area thereon, wherein the patterning is calculated to provide a threading dislocation density having a lattice misfit with an upper limit of 4.5×10¹⁰ cm⁻² and a thermal mismatch with an upper limit of 2.3×10⁹ cm⁻² in a IV-VI crystalline layer grown on a substrate material; and
epitaxially growing the IV-VI crystalline layer on the growing area of the surface of the substrate material to form the IV-VI crystalline structure.

2. The method of claim 1, wherein the IV-VI crystalline layer is PbSe and the substrate material is Si(111).
